(19) United States
(12) Patent Application Publication
(10) Pub. No.: US 2025/0248128 A1
(43) Pub. Date: Jul. 31, 2025

(54) COMPACT DIODE FOR ELECTROSTATIC DISCHARGE (ESD) PROTECTION

(71) Applicant: QUALCOMM Incorporated, San Diego, CA (US)

(72) Inventors: Chenjie TANG, San Diego, CA (US); William Clinton Burling PEATMAN, San Diego, CA (US)

(21) Appl. No.: 18/429,152

(22) Filed: Jan. 31, 2024

(51) Int. Cl. H01L 27/02; H01L 21/48; H01L 23/498

(52) U.S. Cl. CPC H10D 89/611; H01L 21/4846; H01L 23/498; H10D 89/10

(57) ABSTRACT

An electrostatic discharge (ESD) diode is described. The ESD diode includes discrete first-type regions on a substrate. The ESD diode also includes a comb-shaped second-type region on the substrate. Each of the discrete first-type regions of the ESD diode is placed between and contained within two adjacent fingers of the comb-shaped second-type region on the substrate.

### TECHNICAL FIELD

The present disclosure relates to integrated circuits (ICs). More specifically, aspects of the present disclosure relate to a compact diode for electrostatic discharge (ESD) protection.

### BACKGROUND

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing. Although existing methods of fabricating IC devices are adequate for their intended purposes, they are not entirely satisfactory in all respects.

Additionally, the design complexity of mobile radio frequency (RF) chips (e.g., mobile RF transceivers) is complicated by added circuit functions for supporting communications enhancements. As a result, die area savings is critical for cost reduction of RF front end modules utilized by mobile RF chips. In particular, developing a smaller electrostatic discharge (ESD) diode structure with a higher ESD rating is important for layout area savings in power amplifier (PA) designs utilized by these mobile RF chips. Unfortunately, conventional solutions for providing sufficient ESD human body model (HBM) ratings (e.g., 2 kilovolts (kV)) employ a diode size that is often quite large, which consumes a sizable portion of a design layout area. Developing an ESD diode structure with a small layout area is desired for improved PA design.

### SUMMARY

An electrostatic discharge (ESD) diode is described. The ESD diode includes discrete first-type regions on a substrate. The ESD diode also includes a comb-shaped second-type region on the substrate. Each of the discrete first-type regions of the ESD diode is placed between and contained within two adjacent fingers of the comb-shaped second-type region on the substrate.

A method of forming an electrostatic discharge (ESD) diode is described. The method includes forming a plurality of discrete first-type regions on a substrate The method also includes forming a comb-shaped second-type region on the substrate. Each of the discrete first-type regions of the ESD diode is placed between and contained within two adjacent fingers of the comb-shaped second-type region on the substrate.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a wireless device having a wireless local area network module and a radio frequency (RF) front end module for a chipset having a compact diode structure for electrostatic discharge (ESD) protection.

FIG. 2 shows a layout view of a diode string electrostatic discharge (ESD) protection circuit, having a compact diode structure, according to various aspects of the present disclosure.

FIGS. 3A-3C illustrate layout views of multi-finger diode structures, according to various aspects of the present disclosure.

FIGS. 4A-4D illustrate base-collector (BC) diode layouts in heterojunction bipolar transistor (HBT) technology and the cross-sections comparison between the wrap-around diode of FIG. 3A and the multi-finger diode of FIG. 3B, according to various aspects of the present disclosure.

FIGS. 5A-5C illustrate layout views of surrounded diode structures, according to various aspects of the present disclosure.

FIGS. 6A-6C illustrate a surrounded BC diode layout in heterojunction bipolar transistor (HBT) technology and its cross-sections of FIG. 5B, according to various aspects of the present disclosure.

FIGS. 7A and 7B illustrate a BC diode layout in heterojunction bipolar transistor (HBT) technology and the cross-sections heterojunction bipolar transistor (HBT) layouts of a first surrounded diode connected to a second surrounded diode, in accordance with aspects of the present disclosure.

FIG. 8 is a process flow diagram illustrating a method for constructing a compact diode structure for electrostatic discharge (ESD) protection, according to various aspects of the present disclosure.

FIG. 9 is a block diagram showing an exemplary wireless communications system in which a configuration of the present disclosure may be advantageously employed.

FIG. 10 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

As integrated circuit (IC) technology advances, device geometries are reduced. Technological advances in IC materials and design have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing. Although existing methods of fabricating IC devices are adequate for their intended purposes, they are not entirely satisfactory in all respects.

Additionally, the design complexity of mobile radio frequency (RF) chips (e.g., mobile RF transceivers) is complicated by added circuit functions for supporting communications enhancements. As a result, die area savings is critical for cost reduction of RF front end modules utilized by mobile RF chips. In particular, developing a smaller electrostatic discharge (ESD) diode structure with a higher ESD rating is important for layout area savings in power amplifier (PA) designs utilized by these mobile RF chips. Unfortunately, conventional solutions for providing sufficient ESD human body model (HBM) ratings (e.g., 2 kilovolts (kV)) employ a diode size that is often quite large, which consumes a sizable portion of a design layout area. Developing an ESD diode structure with a small layout area is desired for improved PA design.

Various aspects of the present disclosure are directed to a compact ESD diode having two or more discrete first-type regions and a comb-shaped second-type region. The process flow for semiconductor fabrication of the compact ESD diode may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to a substrate of a wafer that is not diced. Similarly, the terms “chip” and “die” may be used interchangeably.

Various aspects of the present disclosure are directed to a compact diode structure for an electrostatic discharge (ESD) protection circuit. In some aspects of the present disclosure, the compact diode structure includes discrete first-type regions on a substrate. Additionally, the compact diode structure includes a comb-shaped second-type region on the substrate. In various aspects of the present disclosure, each of the discrete first-type regions is placed between and contained within two adjacent fingers of the comb-shaped second-type region on the substrate. In some aspects of the present disclosure, each of the discrete first-type regions is placed between and substantially surrounded by two adjacent fingers of the comb-shaped second-type region on the substrate.

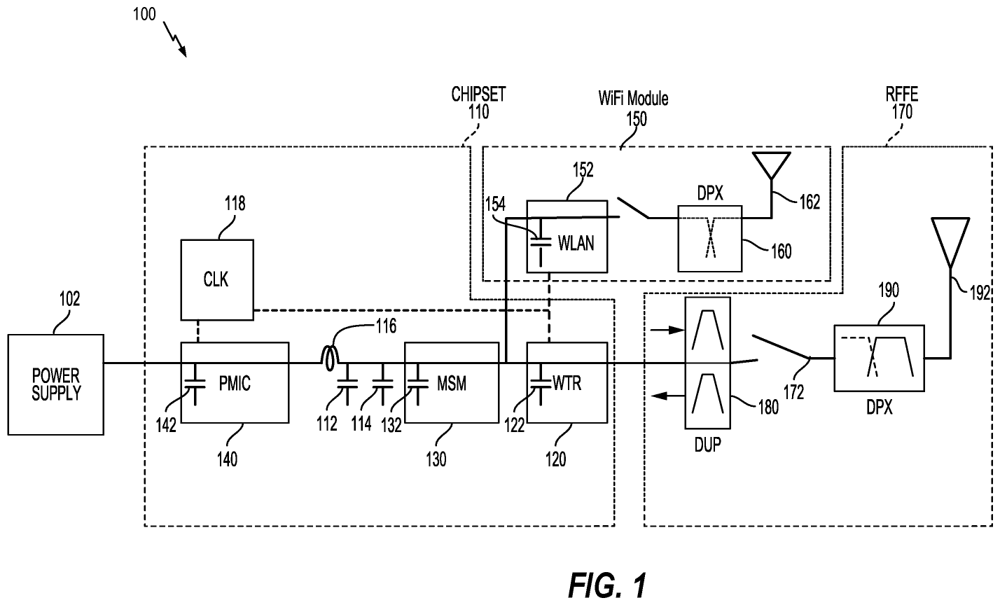

FIG. 1 is a schematic diagram of a wireless device 100 (e.g., a cellular phone or a smartphone) including a compact diode structure for electrostatic discharge (ESD) protection, according to various aspects of the present disclosure. The wireless device 100 has a wireless local area network (WLAN) (e.g., Wi-Fi) module 150 and an RF front end (RFFE) chip 170 for a chipset 110. The Wi-Fi module 150 includes a first diplexer 160 communicably coupling an antenna 162 to a wireless local area network module (e.g., WLAN module 152). The RFFE chip 170 includes the second diplexer 190 communicably coupling an antenna 192 to the wireless transceiver 120 through a duplexer 180 (DUP). An RF switch 172 communicably couples the second diplexer 190 to the duplexer 180. The wireless transceiver 120 and the WLAN module 152 of the Wi-Fi module 150 are coupled to a modem (MSM, e.g., a baseband modem) 130 that is powered by a power supply 102 through a power management integrated circuit (PMIC) 140. The chipset 110 also includes capacitors 112 and 114, as well as an inductor(s) 116 to provide signal integrity. The PMIC 140, the modem 130, the wireless transceiver 120, and the WLAN module 152 each include capacitors (e.g., 142, 132, 122, and 154) and operate according to a clock 118. The geometry and arrangement of the various inductor and capacitor components in the chipset 110 may reduce the electromagnetic coupling between the components.

The wireless transceiver 120 of the wireless device includes a mobile RF transceiver to transmit and receive data for two-way communication. A mobile RF transceiver may include a transmit section for data transmission and a receive section for data reception. For data transmission, the transmit section may modulate an RF carrier signal with data to obtain a modulated RF signal, amplify the modulated RF signal using a power amplifier (PA) to obtain an amplified RF signal having the proper output power level, and transmit the amplified RF signal via the antenna 192 to a base station. For data reception, the receive section may obtain a received RF signal via the antenna and may amplify the received RF signal using a low noise amplifier (LNA) and process the received RF signal to recover data sent by the base station in a communication signal.

The wireless transceiver 120 may include one or more circuits for amplifying these communication signals. The amplifier circuits (e.g., LNA/PA) may include one or more amplifier stages that may have one or more driver stages and one or more amplifier output stages. Each of the amplifier stages includes one or more transistors configured in numerous ways to amplify the communication signals. Distinct options exist for fabricating the transistors that are configured to amplify the communication signals transmitted and received by the wireless transceiver 120.

The wireless transceiver 120 and the RFFE chip 170 may be implemented using semiconductor on insulator (SOI) technology for fabricating transistors of the wireless transceiver 120. Semiconductor on insulator (SOI) technology replaces conventional semiconductor (e.g., silicon) substrates with a layered semiconductor-insulator-semiconductor substrate for reducing parasitic device capacitance and improving performance in the RFFE chip 170.

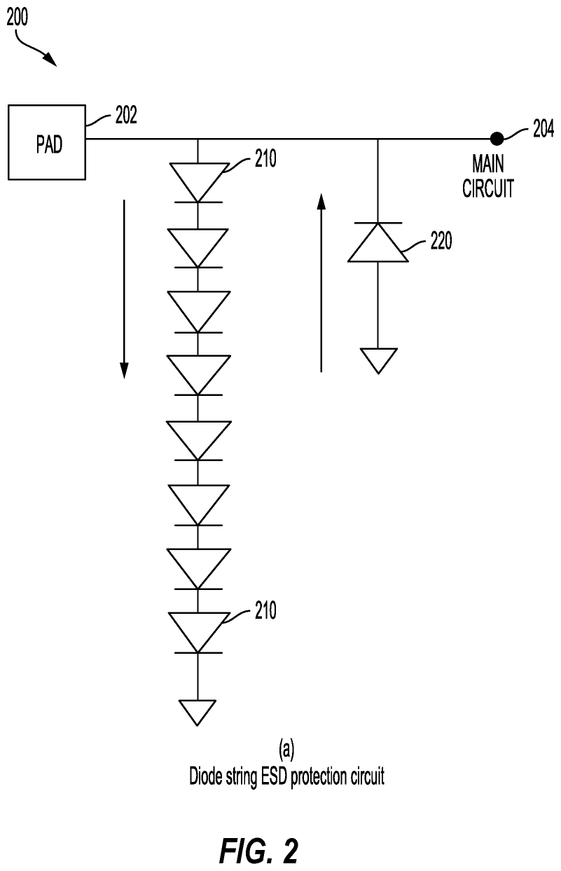

The design complexity of mobile radio frequency (RF) chips (e.g., the wireless device 100) is complicated by added circuit functions for supporting communications enhancements. As a result, die area savings is critical for cost reduction of RF front end modules (e.g., RFFE chip 170) utilized by mobile RF chips, such as the wireless device 100. In particular, developing a smaller electrostatic discharge (ESD) diode structure with a higher ESD rating is important for layout area savings in power amplifier (PA) designs (e.g., LNA/PA) utilized by the wireless device 100, for example, as shown in FIG. 2.

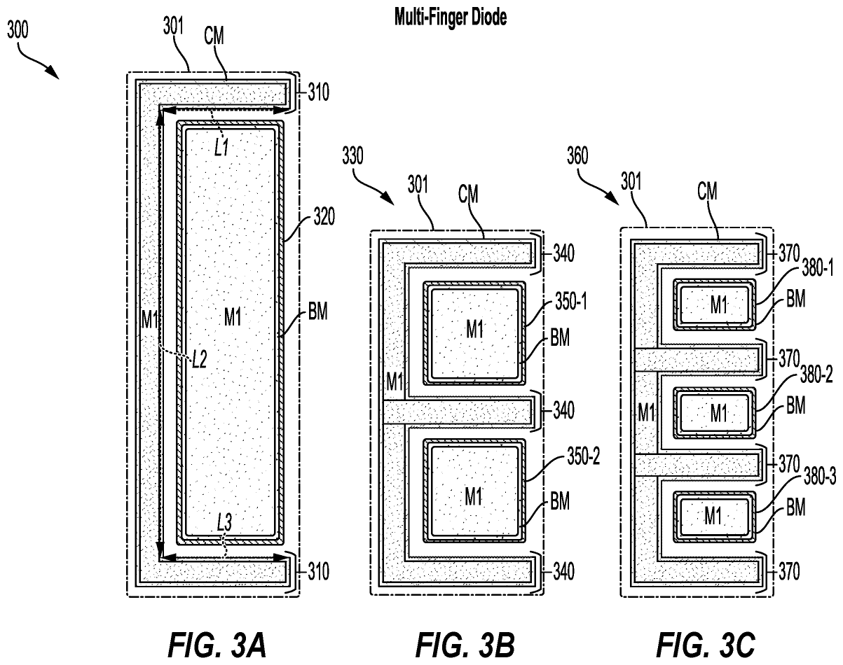

FIG. 2 shows a layout view of a diode string electrostatic discharge (ESD) protection circuit 200, having a compact diode structure, according to various aspects of the present disclosure. As shown in FIG. 2, the ESD protection circuit 200 includes a pad 202 coupled to a main circuit 204, such as the wireless device 100. In this example, the ESD protection circuit 200 includes a string of diodes 210 coupled in series to provide a string diode ESD protection circuit and a reverse diode 220 between the pad 202 and the main circuit 204. According to various aspects of the present disclosure, the ESD protection circuit 200 employs a compact diode size solution for providing a sufficient ESD human body model (HBM) rating (e.g., 2 kV). By contrast, conventional solutions for providing a sufficient ESD HBM rating are often quite large, which consumes a sizable portion of a design layout area. The ESD diode structure of the ESD protection circuit 200 beneficially consumes a smaller layout area for improved power amplifier (PA) design of, for example, the ESD protection circuit 200. A compact diode structure for implementing the ESD protection circuit 200 is further illustrated, for example, in FIGS. 3A-3C.

FIGS. 3A-3C illustrate layout views of multi-finger diode structures, according to various aspects of the present disclosure. Various aspects of the present disclosure recognize that a diode electrostatic discharge (ESD) human body model (HBM) voltage is proportional to a diode effective periphery rather than a diode area. FIG. 3A illustrates a wrap-around diode 300 (e.g., a PN-junction diode), in which an effective periphery of the wrap-around diode 300 is defined by a length of a contact metal (CM) supporting a first metallization (M1) layer of an N-type region 310 adjunct to a P-type region 320 (e.g., L1+L2+L3). In this example, the P-type region 320 (e.g., a base mesa) supports a base metal (BM) and an M1 layer, and an isolation 301 is also shown. While the wrap-around diode 300 provides an increased effective periphery relative to a conventional straight diode structure, various aspects of the present disclosure are directed to compact diode structures for ESD protection, for example, as shown in FIGS. 3B and 3C.

FIG. 3B illustrates a multi-finger diode 330 having an increased effective periphery relative to the wrap-around diode 300 shown in FIG. 3A. As shown in FIG. 3B, a P-type region 350 is divided into multiple regions (e.g., 350-1, 350-2) surrounded by an N-type region 340, in which the number of fingers equals two (2). In this example, the effective periphery is defined by a length of a contact metal (CM) supporting an M1 layer of the N-type region 340 adjunct to the P-type regions 350 (e.g., 350-1, 350-2). In this example, the P-type regions 350 (e.g., base mesa) each support a base metal (BM) and an M1 layer, and the isolation 301 is also shown. As shown in FIG. 3B, the effective periphery is increased by extending the length of the CM of the N-type region 340 adjunct to the P-type regions 350 to form the multi-finger diode 330 structure layout, having an improved ESD HBM rating, while consuming a smaller layout area.

FIG. 3C illustrates a multi-finger diode 360 having an increased effective periphery relative to the multi-finger diode 330 shown in FIG. 3B. As shown in FIG. 3C, a P-type region 380 is further divided into multiple regions (e.g., 380-1, 380-2, 380-3) surrounded by an N-type region 370, in which the number of fingers equals three (3). In this example, the effective periphery is defined by a length of a contact metal (CM) supporting an M1 layer of the N-type region 370 adjunct to the P-type regions 380 (e.g., 380-1, 380-2, 380-3). Additionally, the P-type regions 380 (e.g., base mesa) each support a base metal (BM) and an M1 layer, and the isolation 301 is also shown.

As shown in FIG. 3C, the effective periphery is further increased by extending the length of the CM of the N-type region 370 adjunct to the P-type regions 380 to form the multi-finger diode 360 structure layout, having a further improved ESD HBM rating, while consuming a smaller layout area. According to various aspects of the present disclosure, the N-type region 370 is comb-shaped and includes three (3) or more fingers extending in a first direction and a spine directly coupled to one end of each of the three (3) or more fingers to form a comb-shaped. As shown in FIG. 3C, the spine of the N-type region 370 extends in a second direction substantially orthogonal to the first direction of the three (3) or more fingers.

According to various aspects of the present disclosure, the multi-finger diode 330 shown in FIG. 3B and the multi-finger diode 360 shown in FIG. 3C enlarge a diode effective periphery relative to a conventional straight-line diode. In particular, compared with the traditional straight-line diode, the multi-finger diode structures shown in FIGS. 3B and 3C demonstrate higher ESD ratings with a same breakdown voltage and similar turn-on voltage, and smaller junction capacitance, while consuming a significantly smaller layout area. Although shown as having the N-type region 340 adjunct to the P-type regions 350 in FIG. 3B and the N-type region 370 adjunct to the P-type regions 380 in FIG. 3C, it should be recognized that the N-type and P-type regions may be switched to support a reverse diode connection or a negative supply implementation.

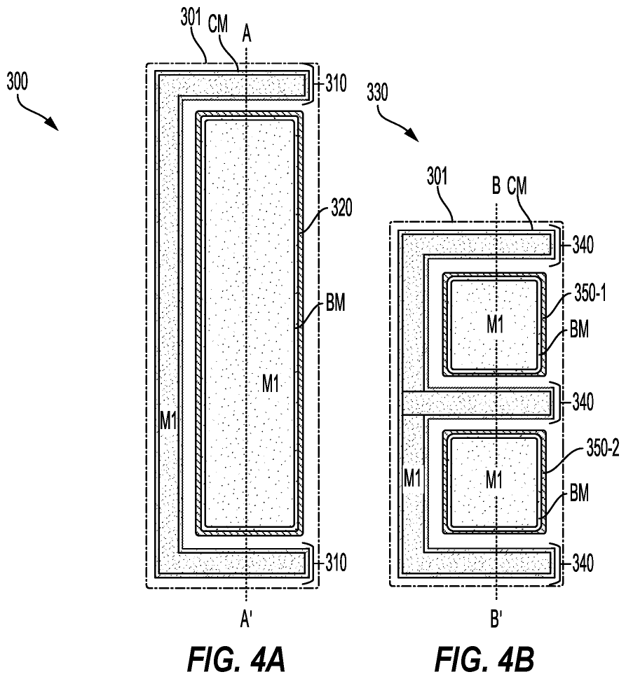

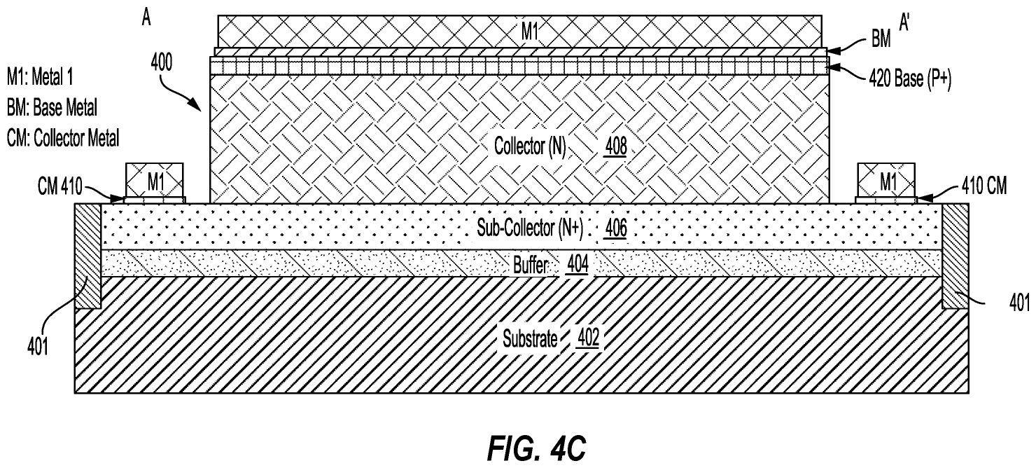

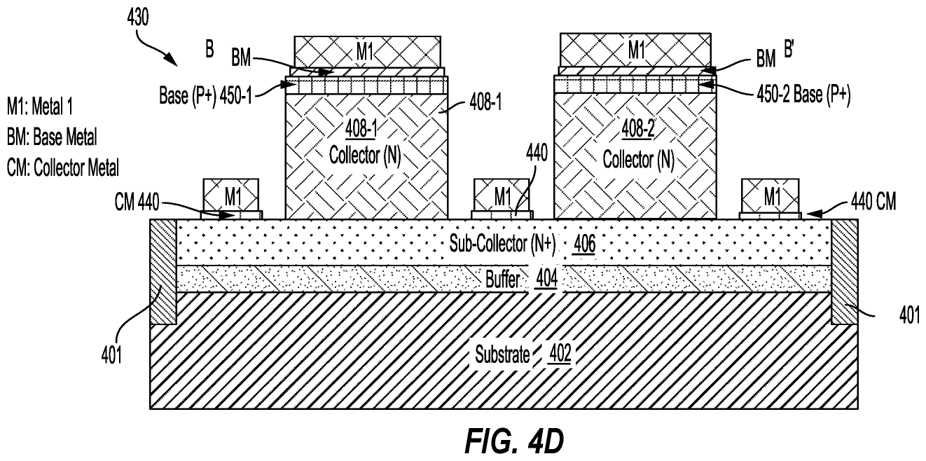

According to various aspects of the present disclosure, the proposed multi-finger diode structure layouts may be implemented using base-collector (BC) diode structures formed in heterojunction bipolar transistor (HBT) technology. The proposed multi-finger diode structures (e.g., 330, 360) shown in FIGS. 3B and 3C support an increased ESD HBM rating in a smaller layout area. As shown in FIG. 3B, a diode P-type region is divided into multiple ones of the P-type regions 350 (e.g., 350-1, 350-2) surrounded by the N-type region 340, in which the number of fingers is greater than or equal to two (e.g., >2). An HBT layout comparison between the multi-finger diode 330 and the wrap-around diode 300 is further illustrated in FIGS. 4A-4D.

FIGS. 4A-4D illustrate a BC diode layout in heterojunction bipolar transistor (HBT) technology comparison between the wrap-around diode 300 of FIG. 3A and the multi-finger diode 330 of FIG. 3B, according to various aspects of the present disclosure. FIG. 4A illustrates the wrap-around diode 300 of FIG. 3A, including a cutline AA′. A cross-sectional view of the wrap-around diode 300 of FIG. 3A along the cutline AA′ is shown in FIG. 4C. FIG. 4B illustrates the multi-finger diode 330 of FIG. 3B, including a cutline BB′. A cross-sectional view of the multi-finger diode 330 of FIG. 3B along the cutline BB′ is shown in FIG. 4D.

FIG. 4C illustrates a cross-sectional view of the wrap-around diode 300 of FIG. 3A along the cutline AA′, according to various aspects of the present disclosure. As shown in the cross-sectional view of FIG. 4C, an HBT implementation of a wrap-around diode 400 includes a substrate 402, supporting a buffer layer 404, and a sub-collector layer 406 (e.g., N+ type sub-collector), including an isolation 401 (e.g., ion implants). In this example, the sub-collector layer 406 supports a collector layer 408 (e.g., N-type), including a base layer 420 (e.g., P-type), which is shown as the P-type region 320 of the wrap-around diode 300 of FIG. 3A. Additionally, a collector metal (CM) 410 is shown as the N-type region 310 of the wrap-around diode 300 of FIG. 3A, including a first metallization (M1) layer. In this example, the M1 layer is shown on a base metal (BM) on the base layer 420.

FIG. 4D illustrates a cross-sectional view of the multi-finger diode 330 of FIG. 3B along the cutline BB′, according to various aspects of the present disclosure. As shown in the cross-sectional view of FIG. 4D, an HBT implementation of a multi-finger diode 430 includes the substrate 402, supporting the buffer layer 404, and the sub-collector layer 406 (e.g., N+ type sub-collector), including the isolation 401 (e.g., ion implants). In this example, the sub-collector layer 406 supports the collector layers 408 (408-1, 408-2), including base layer regions 450 (450-1, 450-2), which are shown as the P-type regions 350 of the multi-finger diode 330 of FIG. 3A. Additionally, a collector metal (CM) 440 is shown as the N-type region 340 of the multi-finger diode 330 of FIG. 3B, including a first metallization (M1) layer. In this example, the M1 layer is shown on a base metal (BM) on the base layer regions 450. The solutions shown in FIGS. 4B and 4D enlarge the diode effective periphery.

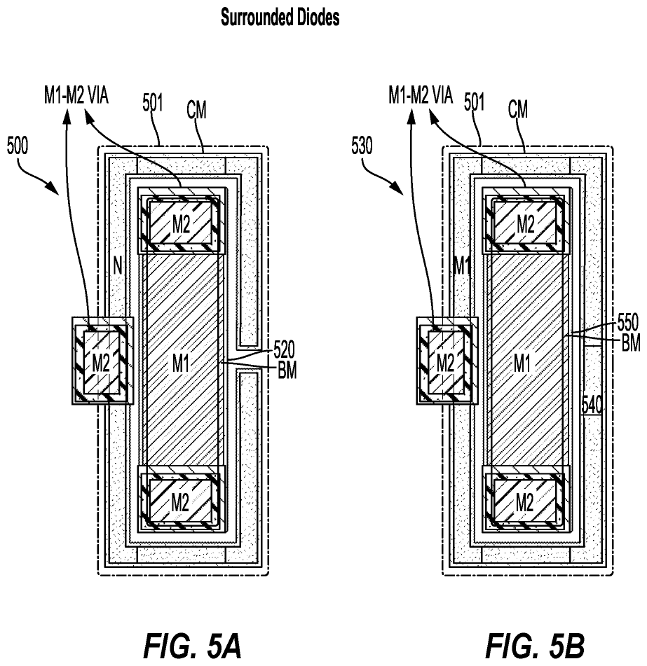

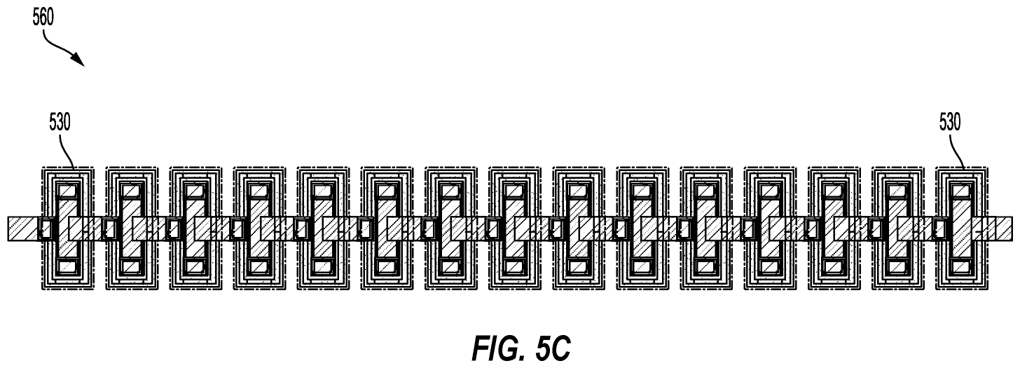

FIGS. 5A and 5B illustrate layout views of surrounded diode structures, according to various aspects of the present disclosure. Various aspects of the present disclosure recognize that a diode electrostatic discharge (ESD) human body model (HBM) voltage is proportional to an extended diode effective periphery rather than a diode area. FIG. 5A illustrates a partially surrounded diode 500, in which an effective periphery of the partially surrounded diode 500 is defined by a length of a contact metal (CM) supporting an M1 layer of an N-type region 510 adjunct to a P-type region 520. Additionally, second metallization (M2) and M1 layer connections to the N-type region 510 adjunct to the P-type region 520 are also shown. In this example, the P-type region 520 (e.g., base mesa), supports a base metal (BM) and an M1 layer, and the isolation 501 is also shown. While the partially surrounded diode 500 provides an increased effective periphery relative to conventional straight diode structures, various aspects of the present disclosure are directed to a surrounded diode structure for ESD protection, for example, as shown in FIG. 5B.

FIG. 5B illustrates a surrounded diode 530 having an increased effective periphery relative to the partially surrounded diode 500 shown in FIG. 5A. As shown in FIG. 5B, a P-type region 550 is completely surrounded by an N-type region 540. In this example, the effective periphery is defined by a length of a contact metal (CM) supporting an M1 layer of the N-type region 540 adjunct to the P-type region 550. In this example, the P-type region 550 (e.g., base mesa), supports a base metal (BM) and an M1 layer, and the isolation 501 is also shown. As shown in FIG. 5B, the effective periphery is increased by extending the length of the CM of the N-type region 540 adjunct to the P-type region 550 to form the surrounded diode 530 structure layout, having an improved ESD HBM rating, while consuming a smaller layout area.

FIG. 5C illustrates a layout view of a diode string electrostatic discharge (ESD) protection circuit 560, having a string of ESD diodes, according to various aspects of the present disclosure. As shown in FIG. 5C, the ESD protection circuit 560 includes a string of the surrounded diodes 530, as shown in FIG. 5B, coupled in series to provide a string diode ESD protection circuit. As shown in FIGS. 5A and 5B, surrounded diode structures are formed, in which the N-type region is covered around a P-type region for increasing ESD ratings. Additionally, M1 layer to M2 layer vias (not shown) are added on N-type and P-type regions, and a diode-to-diode connection can be through the M2 connection, for example, as shown in the ESD protection circuit 560 of FIG. 5C.

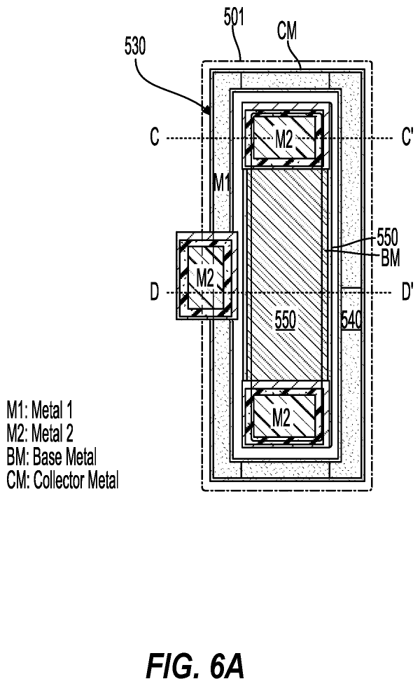

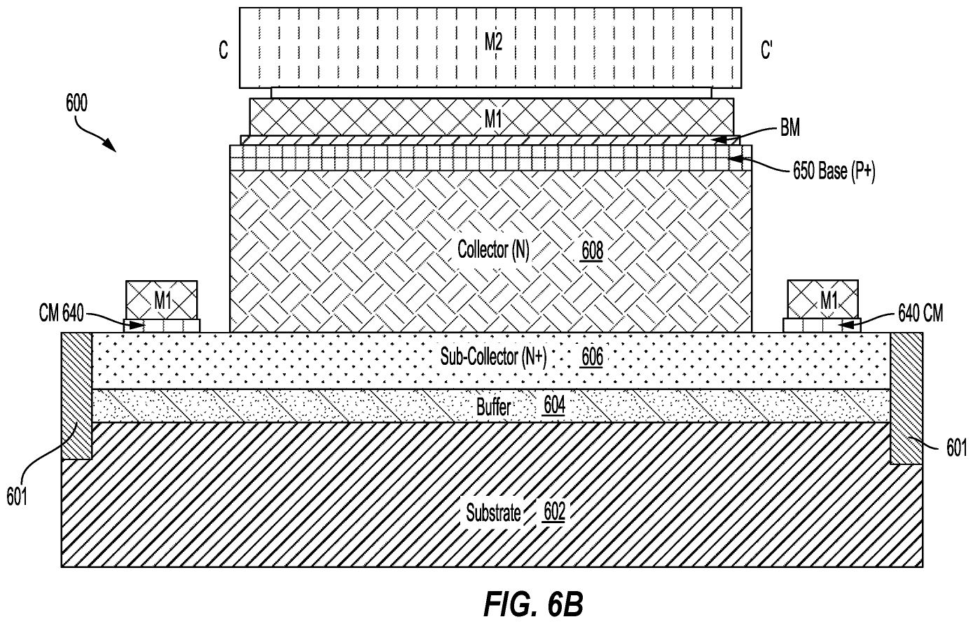

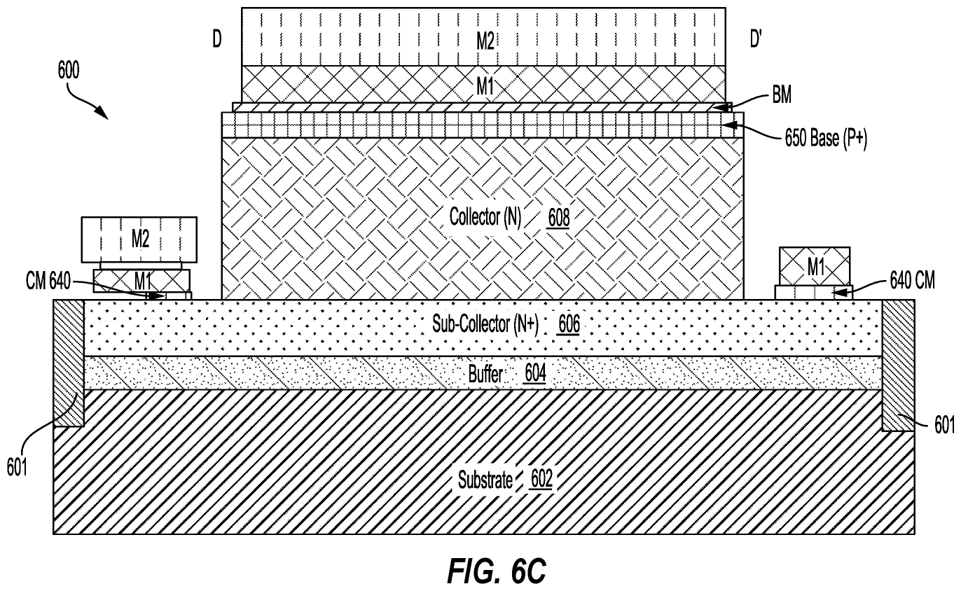

FIGS. 6A-6C illustrate heterojunction bipolar transistor (HBT) layouts of the surrounded diode 530 of FIG. 5B, according to various aspects of the present disclosure. FIG. 6A illustrates the surrounded diode 530 of FIG. 5B, including a cutline CC′. A cross-sectional view of the surrounded diode 530 of FIG. 5B along the cutline CC′ is shown in FIG. 6B. Additionally, FIG. 6A illustrates the surrounded diode 530 of FIG. 5B, including a cutline DD′. A cross-sectional view of the surrounded diode 530 of FIG. 5B along the cutline DD′ is shown in FIG. 6C.

FIG. 6B illustrates a cross-sectional view of the surrounded diode 530 of FIG. 6A along the cutline CC′, according to various aspects of the present disclosure. As shown in the cross-sectional view of FIG. 6B, an HBT implementation of a surrounded diode 600 includes a substrate 602, supporting a buffer layer 604, and a sub-collector layer 606 (e.g., N+ type sub-collector), including the isolation 601 (e.g., ion implants). In this example, the sub-collector layer 606 supports a collector layer 608 (e.g., N-type), including a base layer 650 (e.g., P-type), which is shown as the P-type region 550 of the surrounded diode 530 of FIG. 6A. Additionally, a collector metal (CM) 640 is shown as the N-type region 540 of the surrounded diode 530 of FIG. 6A, including a first metallization (M1) layer. In this example, an M1 layer and a second metallization (M2) layer, stacked on the M1 layer, are shown on a base metal (BM) on the base layer 650.

FIG. 6C illustrates a cross-sectional view of the surrounded diode 530 of FIG. 6A along the cutline DD′, according to various aspects of the present disclosure. As shown in the cross-sectional view of FIG. 6C, an HBT implementation of the surrounded diode 600 includes the substrate 602, supporting the buffer layer 604, and the sub-collector layer 606 (e.g., N+ type sub-collector), including the isolation 601 (e.g., ion implants). In this example, the sub-collector layer 606 supports the collector layer 608 (e.g., N-type), including the base layer 650 (e.g., P-type), which is shown as the P-type region 550 of the surrounded diode 530 of FIG. 6A. Additionally, the collector metal (CM) 640 is shown as the N-type region 540 of the surrounded diode 530 of FIG. 6A, including an M1 layer and an M2 layer stacked on the M1 layer. In this example, the M1 layer and the M2 layer, stacked on the M1 layer, are shown on the base metal (BM) on the base layer 650. The solutions shown in FIGS. 6A-6C enlarge the diode effective periphery. Additionally, the M1 layer and the M2 layer stacked on the collector metal 640 extend beyond the diode effective periphery to enable series connection of the surrounded diode 600 for forming, for example, the ESD protection circuit 560 of FIG. 5C.

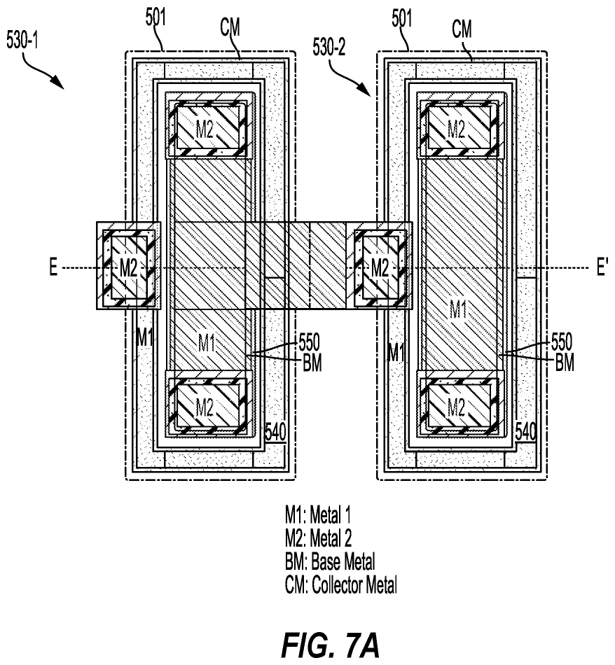

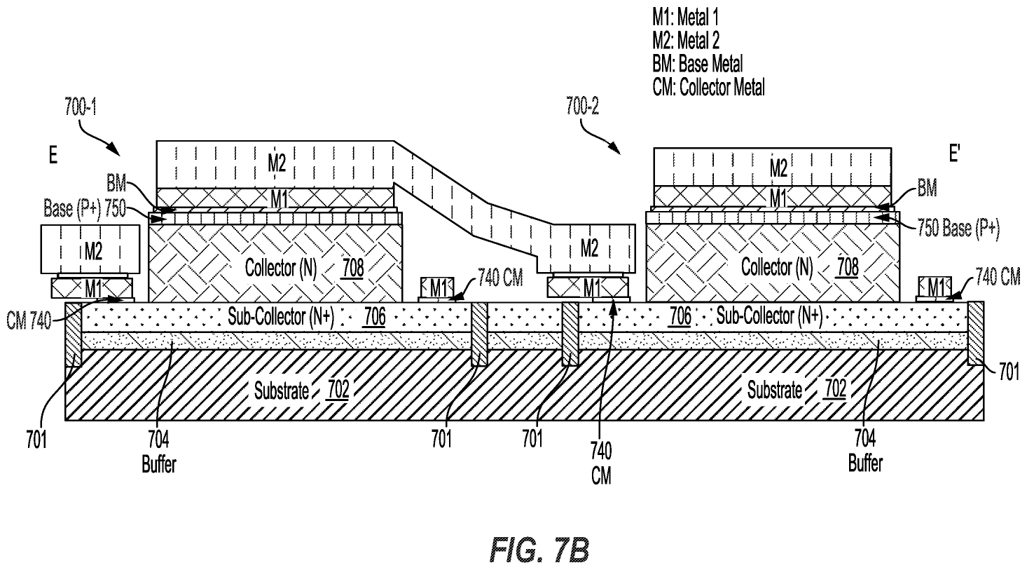

FIGS. 7A and 7B illustrate BC diode layouts in heterojunction bipolar transistor (HBT) technology of a first surrounded diode connected to a second surrounded diode, according to various aspects of the present disclosure. FIG. 7A illustrates a first surrounded diode 530-1 and a second surrounded diode 530-2 (using similar reference numbers to the surrounded diode 530 of FIG. 5B), including a cutline EE′. A cross-sectional view illustrating a series connection through back-end-of-line (BEOL) metallization layers of the first surrounded diode 530-1 and the second surrounded diode 530-2 of FIG. 7A along the cutline EE′ is shown in FIG. 7B.

FIG. 7B illustrates a cross-sectional view of the first surrounded diode 530-1 and the second surrounded diode 530-2 of FIG. 7A along the cutline EE′, according to various aspects of the present disclosure. As shown in the cross-sectional view of FIG. 7B, an HBT implementation of a first surrounded diode 700-1 includes a substrate 702, supporting a buffer layer 704, and a sub-collector layer 706 (e.g., N+ type sub-collector), including the isolation 701 (e.g., ion implants). In this example, the sub-collector layer 706 supports a collector layer 708 (e.g., N-type), including base layer 750 (e.g., P-type), which is shown as the P-type region 550 of the surrounded diode 530-1 of FIG. 7A. Additionally, a collector metal (CM) 740 is shown as the N-type region 540 of the first surrounded diode 530-1 of FIG. 7A, including a first metallization (M1) layer and a second metallization (M2) layer. In this example, an M1 layer is shown on a base metal (BM) on the base layer 750.

FIG. 7B further illustrates a second surrounded diode 700-2, on the substrate 702, supporting the buffer layer 704, and the sub-collector layer 706 (e.g., N+ type sub-collector), including the isolation 701 (e.g., ion implants). In this example, the sub-collector layer 706 supports the collector layer 708 including the base layer 750, which is shown as the P-type region 550 of the second surrounded diode 530-1 of FIG. 7A. Additionally, a collector metal (CM) 740 is shown as the N-type region 540 of the second surrounded diode 530-2 of FIG. 7A, including a first metallization (M1) layer and a second metallization (M2) layer. In this example, an M1 layer is shown on a base metal (BM) on the base layer 750. In various aspects of the present disclosure, the M2 layer of the first surrounded diode 700-1 is coupled to the M2 layer on the M1 layer coupled to the collector metal 740 of the second surrounded diode 700-2 to enable a serial connection for forming, for example, the ESD protection circuit 560 of FIG. 5C.

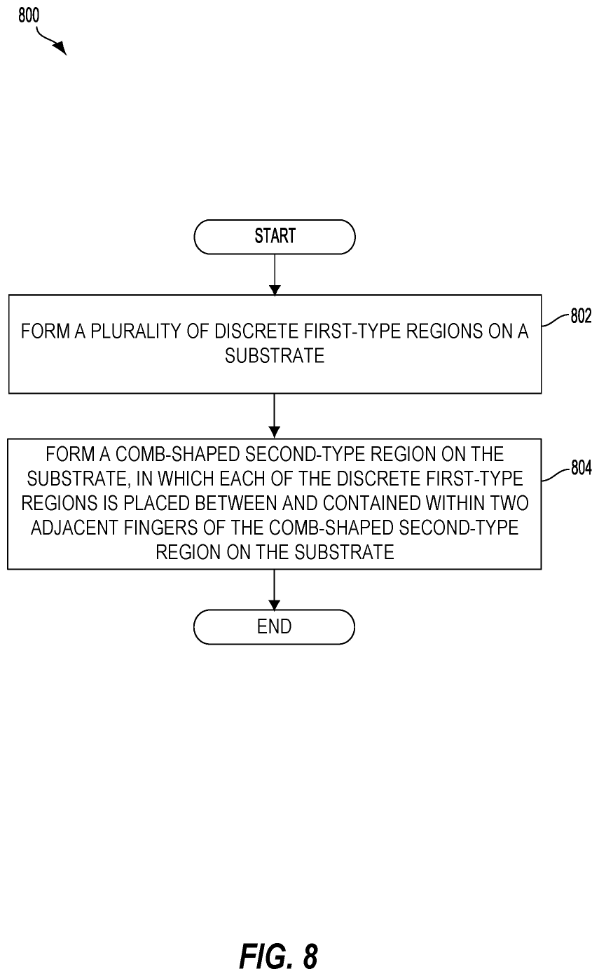

FIG. 8 is a process flow diagram illustrating a method 800 for forming an electrostatic discharge (ESD) diode, according to aspects of the present disclosure. A method 800 begins in block 802, in which a plurality of discrete first-type regions are formed on a substrate. For example, FIG. 3B illustrates a multi-finger diode 330 having an increased effective periphery relative to the wrap-around diode 300 shown in FIG. 3A. As shown in FIG. 3B, a P-type region 350 (e.g., a first-type region) is divided into multiple, discrete regions (e.g., 350-1, 350-2). Additionally, FIG. 3C illustrates the multi-finger diode 360 having an increased effective periphery relative to the multi-finger diode 330 shown in FIG. 3B. As shown in FIG. 3C, the P-type region 380 (e.g., a first-type region) is further divided into multiple, discrete regions (e.g., 380-1, 380-2, 380-3).

At block 804, a comb-shaped second-type region is formed on the substrate, in which each of the discrete first-type regions is placed between and contained within two adjacent fingers of the comb-shaped second-type region on the substrate. For example, as shown in FIG. 3C, the N-type region 370 (e.g., second-type region) is comb-shaped and includes three (3) or more fingers extending in a first direction and a spine directly coupled to one end of each of the three (3) or more fingers to form a comb-shaped. As shown in FIG. 3C, the spine of the N-type region 370 extends in a second direction substantially orthogonal to the first direction of the three (3) or more fingers.

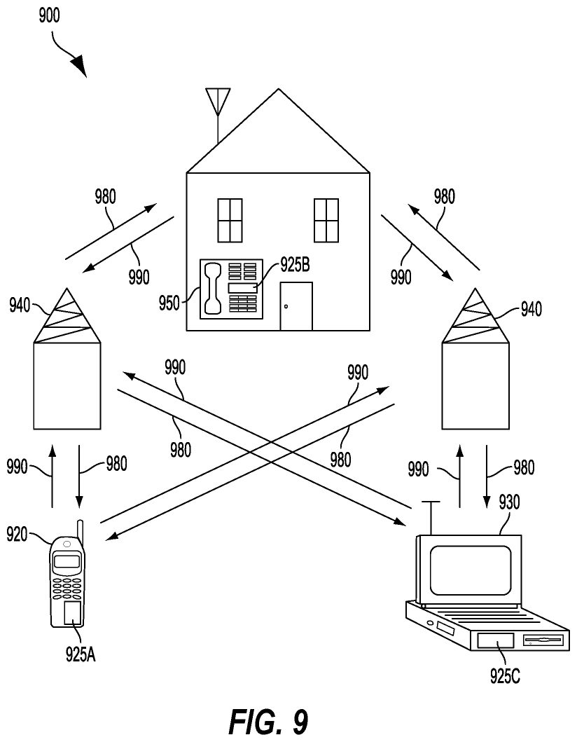

FIG. 9 is a block diagram showing an exemplary wireless communications system 900 in which an aspect of the present disclosure may be advantageously employed. For purposes of illustration, FIG. 9 shows three remote units 920, 930, and 950 and two base stations 940. It will be recognized that wireless communications systems may have many more remote units and base stations. Remote units 920, 930, and 950 include IC devices 925A, 925C, and 925B that include the disclosed compact ESD diode structure. It will be recognized that other devices may also include the disclosed compact ESD diode structure, such as the base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 9 illustrates remote units, according to the aspects of the present disclosure, the present disclosure is not limited to these exemplary illustrated units. Aspects of the present disclosure may be suitably employed in many devices, which include the disclosed compact ESD diode structure.

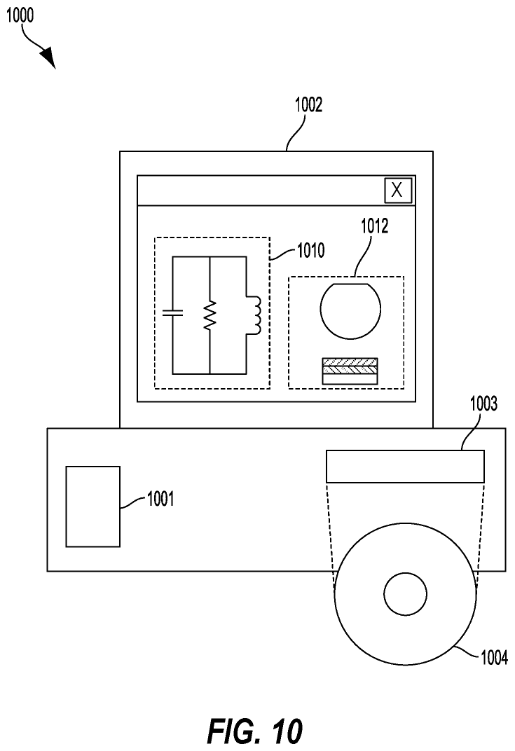

FIG. 10 is a block diagram illustrating a design workstation used for circuit, layout, and logic design of a semiconductor component, such as the compact ESD diode structure disclosed above. A design workstation 1000 includes a hard disk 1001 containing operating system software, support files, and design software such as Cadence or OrCAD. The design workstation 1000 also includes a display 1002 to facilitate a circuit design 1010 or a radio frequency integrated circuit (RFIC) 1012. A storage medium 1004 is provided for tangibly storing the circuit design 1010 or the RFIC 1012. The circuit design 1010 or the RFIC 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit design 1010 or the RFIC 1012 by decreasing the number of processes for designing semiconductor wafers.

Implementation examples are described in the following numbered clauses:
1. An electrostatic discharge (ESD) diode, comprising:
a plurality of discrete first-type regions on a substrate; and
a comb-shaped second-type region on the substrate, in which each of the discrete first-type regions is placed between and contained within two adjacent fingers of the comb-shaped second-type region on the substrate.
2. The ESD diode of clause 1, in which each of the discrete first-type regions is enclosed in the two adjacent fingers of the comb-shaped second-type region on the substrate.
3. The ESD diode of any of clauses 1 or 2, in which each of the discrete first-type regions is partially enclosed in the two adjacent fingers of the comb-shaped second-type region on the substrate.
4. The ESD diode of any of clauses 1-3, in which the plurality of discrete first-type regions comprise a P-type region and the comb-shaped second-type region comprises an N-type region.
5. The ESD diode of any of clauses 1-4, further comprising:
a first metallization (M1) layer on the comb-shaped second-type region; and
a second metallization (M2) layer on the M1 layer.
6. The ESD diode of any of clauses 1-5, further comprising a string of ESD diodes coupled in series through back-end-of-line (BEOL) metallization layers.
7. The ESD diode of any of clauses 1-6, further comprising:
a first metallization (M1) layer on the comb-shaped second-type region; and
a plurality of M1 layers on the plurality of discrete first-type regions.
8. The ESD diode of any of clauses 1-7, in which the comb-shaped second type region includes three or more fingers extending in a first direction and a spine directly coupled to one end of each of the three or more fingers, the spine extending in a second direction substantially orthogonal to the first direction.
9. The ESD diode of any of clauses 1-8, integrated in a radio frequency (RF) front end (RFFE) chip.
10. The ESD diode of clause 9, in which the RFFE chip is incorporated in at least one of a music player, a video player, an entertainment unit, a navigation device, a communications device, a personal digital assistant (PDA), a fixed location data unit, a mobile phone, and a portable computer.
11. A method of forming an electrostatic discharge (ESD) diode, the comprising:
forming a plurality of discrete first-type regions on a substrate; and
forming a comb-shaped second-type region on the substrate, in which each of the discrete first-type regions is placed between and contained within two adjacent fingers of the comb-shaped second-type region on the substrate.
12. The method of clause 11, in which each of the discrete first-type regions is enclosed in the two adjacent fingers of the comb-shaped second-type region on the substrate.
13. The method of any of clauses 11 or 12, in which each of the discrete first-type regions is partially enclosed in the two adjacent fingers of the comb-shaped second-type region on the substrate.
14. The method of any of clauses 11-13, in which the plurality of discrete first-type regions comprise a P-type region and the comb-shaped second-type region comprises an N-type region.
15. The method of any of clauses 11-14, further comprising:
forming a first metallization (M1) layer on the comb-shaped second-type region; and
forming a second metallization (M2) layer on the M1 layer.
16. The method of any of clauses 11-15, further coupling a string of ESD diodes in series through back-end-of-line (BEOL) metallization layers.
17. The method of any of clauses 11-16, further comprising:
forming a first metallization (M1) layer on the comb-shaped second-type region; and
forming a plurality of M1 layers on the plurality of discrete first-type regions.
18. The method of any of clauses 11-17, in which the comb-shaped second type region includes three or more fingers extending in a first direction and a spine directly coupled to one end of each of the three or more fingers, the spine extending in a second direction substantially orthogonal to the first direction.
19. The method of any of clauses 11-18, further comprising integrated in a radio frequency (RF) front end (RFFE) chip.
20. The method of clause 19, further comprising incorporating the RFFE chip is incorporated in at least one of a music player, a video player, an entertainment unit, a navigation device, a communications device, a personal digital assistant (PDA), a fixed location data unit, a mobile phone, and a portable computer.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described herein may be utilized, according to the present disclosure. Accordingly, the appended claims are intended to include within their scope such processes, machines, manufacture, compositions of matter, means, methods, or steps.

What is claimed is:

1. An electrostatic discharge (ESD) diode, comprising:
a plurality of discrete first-type regions on a substrate; and
a comb-shaped second-type region on the substrate, in which each of the discrete first-type regions is placed between and contained within two adjacent fingers of the comb-shaped second-type region on the substrate.

2. The ESD diode of claim 1, in which each of the discrete first-type regions is enclosed in the two adjacent fingers of the comb-shaped second-type region on the substrate.

3. The ESD diode of claim 1, in which each of the discrete first-type regions is partially enclosed in the two adjacent fingers of the comb-shaped second-type region on the substrate.

4. The ESD diode of claim 1, in which the plurality of discrete first-type regions comprise a P-type region and the comb-shaped second-type region comprises an N-type region.

5. The ESD diode of claim 1, further comprising:
a first metallization (M1) layer on the comb-shaped second-type region; and
a second metallization (M2) layer on the M1 layer.

6. The ESD diode of claim 1, further comprising a string of ESD diodes coupled in series through back-end-of-line (BEOL) metallization layers.

7. The ESD diode of claim 1, further comprising:
a first metallization (M1) layer on the comb-shaped second-type region; and
a plurality of M1 layers on the plurality of discrete first-type regions.

8. The ESD diode of claim 1, in which the comb-shaped second type region includes three or more fingers extending in a first direction and a spine directly coupled to one end of each of the three or more fingers, the spine extending in a second direction substantially orthogonal to the first direction.

9. The ESD diode of claim 1, integrated in a radio frequency (RF) front end (RFFE) chip.

10. The ESD diode of claim 9, in which the RFFE chip is incorporated in at least one of a music player, a video player, an entertainment unit, a navigation device, a communications device, a personal digital assistant (PDA), a fixed location data unit, a mobile phone, and a portable computer.

11. A method of forming an electrostatic discharge (ESD) diode, the comprising:
forming a plurality of discrete first-type regions on a substrate; and
forming a comb-shaped second-type region on the substrate, in which each of the discrete first-type regions is placed between and contained within two adjacent fingers of the comb-shaped second-type region on the substrate.

12. The method of claim 11, in which each of the discrete first-type regions is enclosed in the two adjacent fingers of the comb-shaped second-type region on the substrate.

13. The method of claim 11, in which each of the discrete first-type regions is partially enclosed in the two adjacent fingers of the comb-shaped second-type region on the substrate.

14. The method of claim 11, in which the plurality of discrete first-type regions comprise a P-type region and the comb-shaped second-type region comprises an N-type region.

15. The method of claim 11, further comprising:
forming a first metallization (M1) layer on the comb-shaped second-type region; and
forming a second metallization (M2) layer on the M1 layer.

16. The method of claim 11, further coupling a string of ESD diodes in series through back-end-of-line (BEOL) metallization layers.

17. The method of claim 11, further comprising:
forming a first metallization (M1) layer on the comb-shaped second-type region; and
forming a plurality of M1 layers on the plurality of discrete first-type regions.

18. The method of claim 11, in which the comb-shaped second type region includes three or more fingers extending in a first direction and a spine directly coupled to one end of each of the three or more fingers, the spine extending in a second direction substantially orthogonal to the first direction.

19. The method of claim 11, further comprising integrated in a radio frequency (RF) front end (RFFE) chip.

20. The method of claim 19, further comprising incorporating the RFFE chip is incorporated in at least one of a music player, a video player, an entertainment unit, a navigation device, a communications device, a personal digital assistant (PDA), a fixed location data unit, a mobile phone, and a portable computer.
